(19) United States
(12) Patent Application Publication
(10) Pub. No.: US 2009/0181329 A1
(43) Pub. Date: Jul. 16, 2009

(54) METHOD FOR MANUFACTURING A LIQUID JET HEAD, A LIQUID JET HEAD, AND A LIQUID JET APPARATUS

(75) Inventor: Yasuyuki Matsumoto, Azumino - shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SEIKO EPSON CORPORATION, Tokyo (JP)

(21) Appl. No.: 12/350,780

(22) Filed: Jan. 8, 2009

(30) Foreign Application Priority Data
Jan. 8, 2008 (JP) 2008-001270
Dec. 22, 2008 (JP) 2008-326468

(51) Int. Cl. G03F 7/00; B41J 2/04

(52) U.S. Cl. 430/320; 347/54

(57) ABSTRACT

When a liquid passage is formed by etching a passage forming substrate by using a protective film formed on the surface of the passage forming substrate, there are provided a first step of forming the protective film, as a process of forming the protective film having a predetermined pattern, a second step of forming a resist film by applying a positive resist on the protective film and subjecting the positive resist to pre-baking, a third step of selectively removing the resist film by selectively exposing and developing the resist, a fourth step of selectively removing the protective film by performing dry etching at a temperature equal to or lower than a temperature at which the pre-baking is performed, a fifth step of removing a degeneration layer formed on the surface of the resist film in the third step, and a sixth step of removing the resist film by again exposing and developing the resist film.

### BACKGROUND

The entire disclosure of Japanese Patent Application No. 2008-001270, filed Jan. 8, 2008 is incorporated by reference herein.

The entire disclosure of Japanese Patent Application No. 2008-326468, filed Dec. 22, 2008 is incorporated by reference herein.

1. Technical Field

The present invention relates to a method of manufacturing a liquid jet head including a passage forming substrate in which pressure generating chambers communicating with nozzles are formed by etching, and particularly to a method of manufacturing an ink jet print head for ejecting ink droplets as liquid droplets, a liquid jet head, and a liquid jet apparatus.

2. Related Art

As a representative example of the liquid jet head ejecting liquid droplets, there is known a liquid jet head which includes a passage forming substrate provided with pressure generating chambers and pressure generating means provided on one surface of the passage forming substrate and which ejects ink droplets through nozzles by allowing the pressure generating units to apply pressure to the inside of the pressure generating chambers.

For example, the pressure generating chambers of the ink jet print head are formed by performing anisotropic etching on the passage forming substrate by use of a protective film (mask film) having a predetermined pattern as a mask and formed on the passage forming substrate (for example, JP-A-2007-216564).

The protective film used when the pressure generating chambers are formed is formed so as to have the predetermined pattern by a photolithography method. Specifically, a resist film is formed by applying, exposing, developing a resist on the protective film formed on the entire surface of the passage forming substrate, the protective film is patterned by etching by use of the resist film as a mask, and then the resist film is removed.

Here, the protective film can be patterned by wet etching or dry etching. However, in an ink jet print head having a configuration described in Patent Document 1, for example, the protective film is generally subjected to the dry etching, since both surfaces of the passage forming substrate are processed beforehand. In order to perform the patterning on the protective film by the wet etching, the surface opposite the projective film of the passage forming substrate need to be protected so as not to be smeared with an etching liquid, thereby complicating a work.

The patterning of the protective film can be performed relatively easily and satisfactorily by patterning the protective film by the dry etching. However, a problem may occur in that it is difficult to remove the resist film used as the mask when the patterning is performed.

As a method of removing the resist film, a method of removing the resist film by use of an organic removing liquid can be used, for example. However, a problem may also occur in that the organic removing liquid badly affects an organic substance such as an adhesive used to attach a substrate due to a strong removing strength. Alternatively, a method of removing the resist film by O2 plasma ashing can be used. However, a problem may occur in that work efficiency is poor due to relatively long processing time.

These problems also occur not only in the ink jet print head ejecting the ink droplets but also in other liquid jet heads ejecting liquid droplets other than the ink droplets.

The invention is devised in view of the above-mentioned circumstance and an object of the invention is to provide a method of manufacturing a liquid jet head capable of improving manufacture efficiency by satisfactorily and efficiently removing a resist film as a mask of a protective film when pressure generating chambers are formed, a liquid jet head, and a liquid jet apparatus.

### SUMMARY

In order to solve the above-mentioned problems, according to an aspect of the invention, there is provided a method of manufacturing a liquid jet head which includes a passage forming substrate provided with a liquid passage including a pressure generating chamber communicating with a nozzle for ejecting liquid droplets and pressure generating member provided above one surface of the passage forming substrate and generating pressure in the pressure generating chamber, the method comprising: forming the liquid passage by etching the passage forming substrate by using a protective film, which has a predetermined pattern formed above a surface of the passage forming substrate, as a mask, forming the protective film above the entire surface of the passage forming substrate, as a process of forming the protective film having the predetermined pattern; forming a resist film by applying a positive resist on the protective film and subjecting the positive resist to pre-baking; removing selectively the resist film by selectively exposing and developing the resist film; removing selectively the protective film by performing dry etching at a temperature equal to or lower than a temperature at which the pre-baking is performed; removing a degeneration layer formed on a surface of the resist film in removing selectively the resist film; and removing the resist film by again exposing and developing the resist film.

In the invention, since the output is set to be relatively low at the time of patterning the resist film by the dry etching, the photosensitivity of the resist film is not completely lost even in the patterning on the resist film. In consequence, the resist film can be effectively removed after the patterning on the protective film. Accordingly, it is possible to considerably improve manufacture efficiency of the liquid jet head.

Here, it is preferable that in removing a degeneration layer, the degeneration layer is removed by use of ozone water. With such a step, it is possible to remove the degeneration layer satisfactorily and easily without badly affecting the periphery.

It is preferable that in removing selectively the protective film, the protective film is subjected to dry etching at a state where the passage forming substrate is maintained at a temperature of 80° C. or less. With such a step, it is possible to subject the protective film to the patterning, while surely preventing the photosensitivity of the resist film from being lost.

The invention is particularly efficient, when the protective film is formed of silicon nitride and in removing selectively the protective film, the protective film is removed by plasma etching by use of carbon tetrafluoride. In this case, since the degeneration layer having a hydrophobic property is formed on the surface of the resist film in removing selectively the protective film, a development liquid is splashed in the degeneration layer. Therefore, it is difficult to remove the resist film. However, in the invention, since the degeneration layer is removed before the removal of the resist film by development, it is possible to easily remove the resist film.

It is preferable that in removing selectively the resist film, the resist film is selectively removed and then the resist film is additionally subjected to post-baking. Accordingly, it is possible to more satisfactorily form the resist film.

According to another aspect of the invention, there is provided a liquid jet head manufactured by the above-described method. With such a configuration, it is possible to provide the liquid jet head having a predetermined capability with relatively low cost.

According to still another aspect of the invention, there is provided a liquid jet apparatus including the liquid jet head. With such a configuration, it is possible to provide the liquid jet apparatus having a predetermined capability with relatively low cost.

### BRIEF DESCRIPTION OF THE DRAWINGS

FIG. 1 is an exploded perspective view illustrating a print head according to an embodiment.

FIG. 2 is a top view and a sectional view illustrating the print head according to the embodiment.

FIG. 3 is a sectional view illustrating a process of manufacturing the print head according to the embodiment.

FIG. 4 is a sectional view illustrating the process of manufacturing the print head according to the embodiment.

FIG. 5 is a sectional view illustrating the process of manufacturing the print head according to the embodiment.

FIG. 6 is a sectional view illustrating the process of manufacturing the print head according to the embodiment.

FIG. 7 is a sectional view illustrating the process of manufacturing the print head according to the embodiment.

FIG. 8 is a schematic diagram illustrating a maintenance stage of a dry etching apparatus.

FIG. 9 is a perspective view illustrating an overall configuration of a printing apparatus according to the embodiment.

10: PASSAGE FORMING SUBSTRATE
12: PRESSURE GENERATING CHAMBER
13: INK SUPPLY PASSAGE
14: COMMUNICATION PASSAGE
15: COMMUNICATION SECTION
20: NOZZLE PLATE
21: NOZZLE
30: PROTECTIVE SUBSTRATE
31: PIEZOELECTRIC ELEMENT PRESERVER
32: RESERVOIR SECTION
33: THROUGH-HOLE
40: COMPLIANCE SUBSTRATE
50: ELASTIC FILM
52: PROTECTIVE FILM
55: INSULATING FILM
60: LOWER ELECTRODE FILM
70: PIEZOELECTRIC LAYER
80: UPPER ELECTRODE FILM
90: LEAD ELECTRODE
110: PASSAGE FORMING SUBSTRATE WAFER
130: PROTECTIVE SUBSTRATE WAFER
200: RESIST FILM
201: OPENING
202: DEGENERATION LAYER
250: MASK MEMBER
251: OPENING
300: PIEZOELECTRIC ELEMENT

### DESCRIPTION OF EXEMPLARY EMBODIMENTS

Hereinafter, an embodiment of the invention will be described in detail.

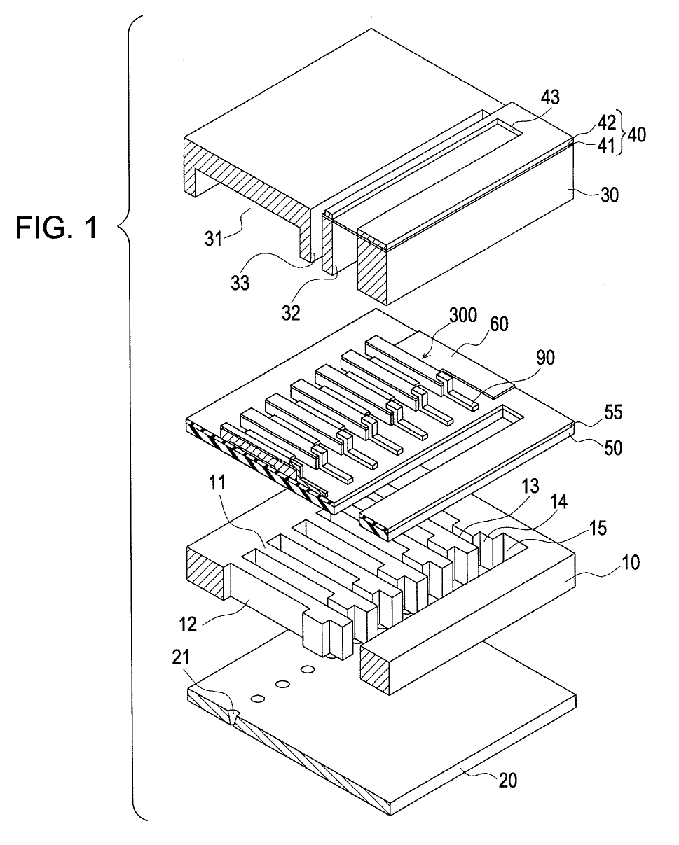

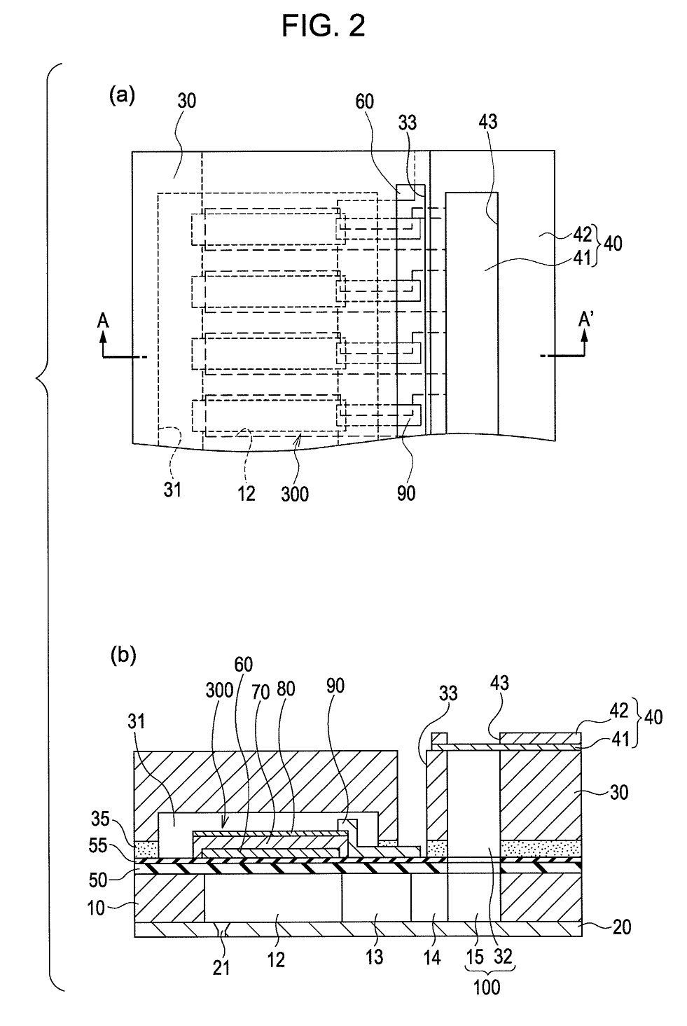

FIG. 1 is an exploded perspective view illustrating the overall configuration of an ink jet print head as an example of a liquid jet head. FIG. 2 is a top view and a sectional view taken along the line A-A′ of FIG. 1.

As illustrated, a passage forming substrate 10 is formed of a silicon single crystal substrate with a face orientation (110), for example. In addition, an elastic film 50 formed of an oxide film is formed on one surface of the passage forming substrate. Pressure generating chambers 12 partitioned by a plurality of partition walls 11 are arranged in parallel in a width direction (transverse direction) in the passage forming substrate 10. Ink supply passages 13 and communication passages 14 are partitioned by the partition walls 11 in one ends of the pressure generating chambers 12 of the passage forming substrate 10 in a longitudinal direction. A communication section 15 forming a part of a reservoir 100, which is a common ink chamber (liquid chamber) of the pressure generating chambers 12, is formed in one end of the communication passages 14. An ink passage (the pressure generating chambers 12, the ink supply passages 13, the communication passages 14, and the communication section 15) including the pressure generating chambers 12 is formed in the passage forming substrate 10.

A nozzle plate 20 through which nozzles 21 respectively communicating with the pressure generating chambers 12 are punched is fixed and adhered to an opening surface of the passage forming substrate 10 by an adhesive or a heat welding film. The nozzle plate 20 is formed of glass ceramics, a silicon single crystal substrate, stainless steel, or the like.

The above-described elastic film 50 is formed opposite the opening surface of the passage forming substrate 10 and an insulating film 55 formed of an oxide film material different that of the elastic film 50 is formed on the elastic film 50. Piezoelectric elements 300 each including a lower electrode film 60, a piezoelectric layer 70, and an upper electrode film 80 are formed on the insulating film 55. In this embodiment, the lower electrode film 60 serves as a common electrode of the piezoelectric element 300 and the upper electrode film 80 serves as an individual electrode of the piezoelectric element 300, and vice versa so as to match with the configuration of a driving circuit or a wiring. Here, the piezoelectric elements 300 and all vibration plates to be displaced due to drive of the piezoelectric elements 300 are referred to as actuators. The vibration plate is a portion which forms one surface of the pressure generating chamber 12 and is deformed by drive of the piezoelectric element 300. In this embodiment, the elastic film 50, the insulating film 55, and the lower electrode film 60 serve as the vibration plate. Of course, the invention is not limited thereto. For example, only the lower electrode film 60 may serve as the vibration plate without providing the elastic film 50 and the insulating film 55. Alternatively, the piezoelectric elements 300 may practically serve as the vibration plate.

A protective substrate 30 including piezoelectric element preservers 31 each ensuring a space in an area opposite the piezoelectric element 300 so as not to interrupt the movement of the piezoelectric element is joined onto the passage forming substrate 10. Since the piezoelectric element is formed inside the piezoelectric element preserver 31, the piezoelectric element 300 is preserved not to be affected from the outside environment, even though the piezoelectric element preserver 31 is not necessarily sealed in an airtight manner. A reservoir section 32 forming at least a part of a reservoir 100 is provided in the protective substrate 30. In this embodiment, the reservoir section 32 is formed to be perforated through the protective substrate 30 in a thickness direction and extend in the width direction of the pressure generating chambers 12. In addition, the reservoir section forms the reservoir 100 which communicates with the communication section 15 of the passage forming substrate 10 and serves as a common ink chamber of the pressure generating chambers 12. A through-hole 33 perforated through the protective substrate 30 in the thickness direction is formed in an area between the piezoelectric element preserver 31 and the reservoir section 32 of the protective substrate 30. Lead electrodes 90 are drawn from the piezoelectric elements 300, respectively, so that the vicinities of the ends thereof are exposed in the through-hole 33. Examples of a material of the protective substrate 30 include glass, a ceramic material, metal, and resin, but it is desirable that the protective substrate is formed of a material having the substantially same thermal expansibility as that of the passage forming substrate 10.

A compliance substrate 40 including a sealing film 41 and a fixing plate 42 is joined in an area corresponding to the reservoir section 32 of the protective substrate 30. The sealing film 41 is made of a material having a low rigidity and a flexible property. One surface of the reservoir section 32 is sealed by the sealing film 41. The fixing plate 42 is made of a material such as metal having a hard property. Since an area opposite the reservoir 100 of the fixing plate 42 is an opening 43 completely removed in the thickness direction, one surface of the reservoir 100 is sealed only by the sealing film 41 having a flexible property.

In the ink jet print head having the above-described configuration, ink is supplied from an ink introduction port connected to external ink supplying means (not shown), the inside from the reservoir 100 to the nozzles 21 is filled with the ink, and ink droplets are ejected from the nozzles 21 by applying voltage between the lower electrode film 60 and the upper electrode film 80 corresponding to each of the pressure generating chambers 12 in accordance with a print signal supplied from a driving circuit (not shown), deforming the piezoelectric elements 300 so as to be bent, and increasing the pressure of each of the pressure generating chambers 12.

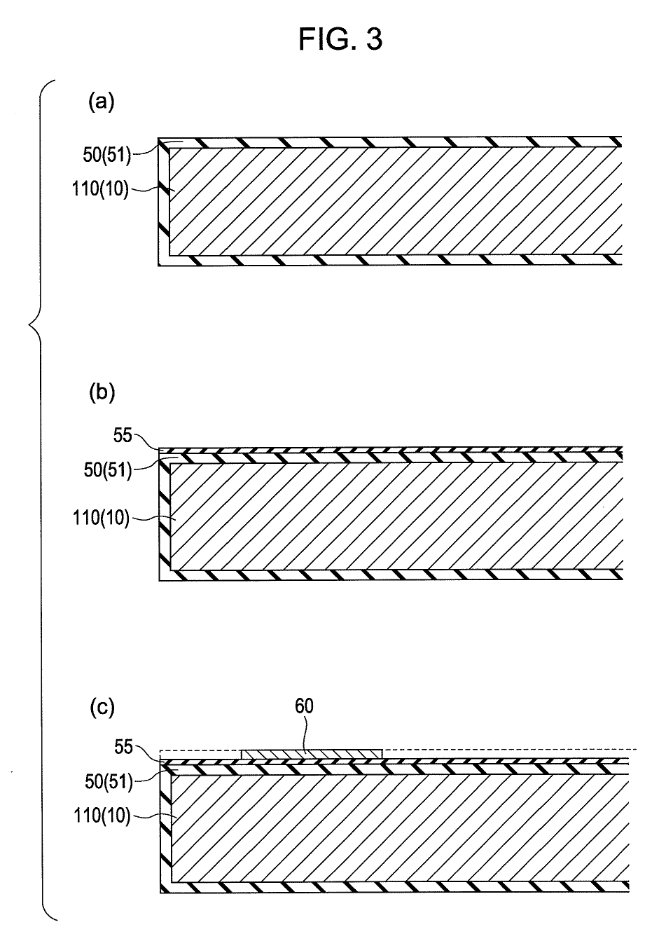

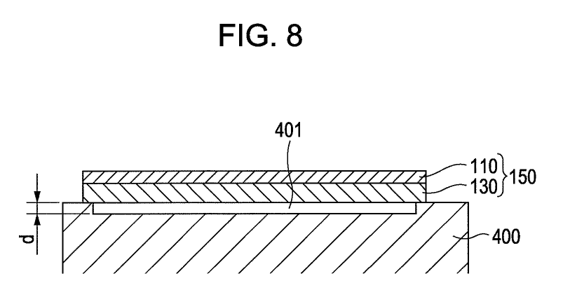

Hereinafter, a method of manufacturing the liquid jet head (ink jet print head) will be descried with reference to FIGS. 3 to 8 according to the invention. FIGS. 3 to 7 are sectional views illustrating the pressure generating chamber of the ink jet print head in the longitudinal direction. FIG. 8 is a schematic diagram illustrating a maintenance stage of a dry etching apparatus. As described below, a plurality of the passage forming substrates 10 and the protective substrates 30 are integrally formed in the silicon wafer and finally separated into each substrate.

First, as shown in (a) of FIG. 3, an oxide film 51 forming the elastic film 50 is formed on the surface of a passage forming substrate wafer 110 as a silicon wafer. For example, the surface of the passage forming substrate wafer 110 is subjected to thermal oxidation to form the oxide film 51 made of silicon dioxide. Subsequently, as shown in (b) of FIG. 3, the insulating film 55 made of the oxide film different from the material of the elastic film 50 is formed on the elastic film 50 (the oxide film 51). Specifically, a zirconium (Zr) layer is formed on the elastic film 50 (the oxide film 51) by a sputtering method, for example, and then the insulating film 55 formed of zirconium oxide (ZrO2) by performing the thermal oxidation on the zirconium layer is formed.

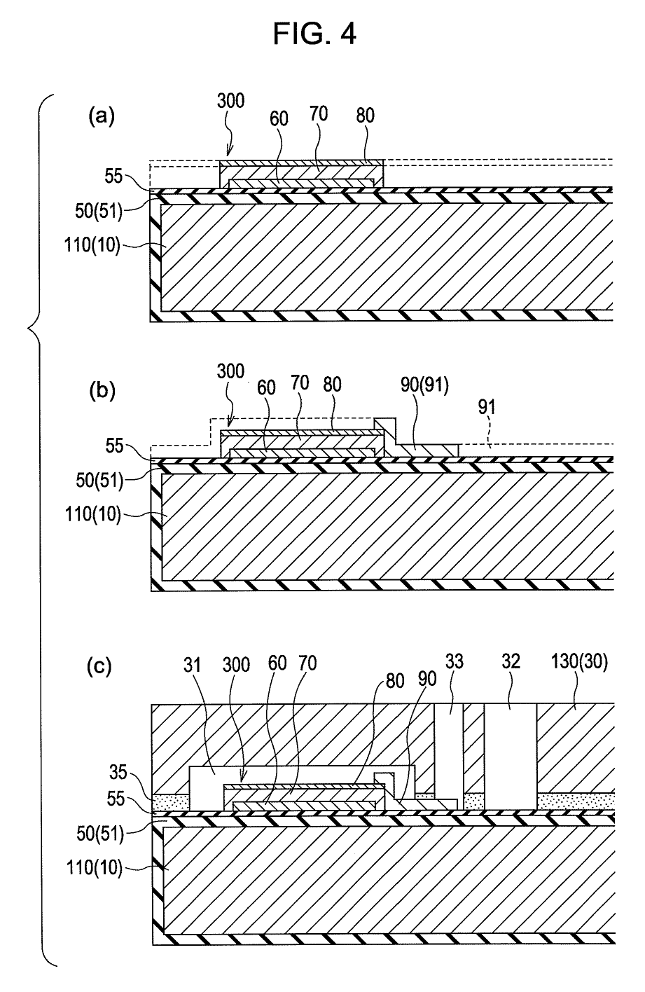

Subsequently, as shown in (c) of FIG. 3, the low electrode film 60 is formed by laminating platinum and iridium layers on the insulating film 55, and then the lower electrode film 60 is patterned in a predetermined shape. Subsequently, as shown in (a) of FIG. 4, each of the piezoelectric elements 300 is formed by forming the piezoelectric layer 70 made of lead zirconate titanate (PZT), for example, and the upper electrode film 80 made of iridium (Ir), for example and patterning the piezoelectric layer 70 and the upper electrode film 80.

As the material of the piezoelectric layer 70, a ferroelectric-piezoelectric material such as lead zirconate titanate (PZT) or relaxor ferroelectric formed by adding niobium, nickel, magnesium, bismuth, or yttrium to lead zirconate titanate may be used, for example. In order to form the piezoelectric layer 70 in this embodiment, there is used a so-called sol-gel method, as a method of forming the piezoelectric layer 70, of applying and drying a so-called sol obtained by dissolving and dispersing a metal organic substance with a solvent to make a gel and baking the gel at a high temperature to obtain the piezoelectric layer 70 made of metal oxide. The method of the forming the piezoelectric layer 70 is not particularly limited, but an MOD method or a sputtering method may be used.

Subsequently, as shown in (b) of FIG. 4, the lead electrode 90 is formed. Specifically, a metal layer 91 made of gold (Au), for example, is formed on the entire surface of the passage forming substrate wafer 110, and then the metal layer 91 is patterned in each of the piezoelectric elements 300 to form the lead electrode 90.

Subsequently, as shown in (c) of FIG. 4, a protective substrate wafer 130 as a silicon wafer is joined to the piezoelectric elements 300 of the passage forming substrate wafer 110 by a joining member 35. In addition, the piezoelectric element preserver 31, reservoir section 32, and the through-hole 33 are formed in advance in the protective substrate wafer 130.

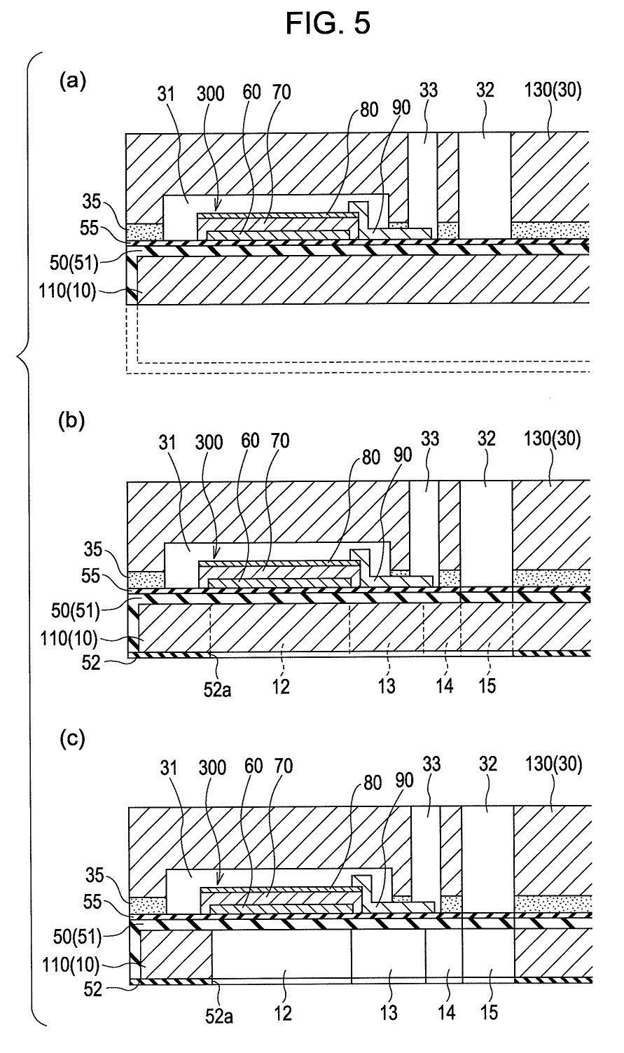

Subsequently, as shown in (a) of FIG. 5, the passage forming substrate wafer 110 is formed with a predetermined thickness by processing the opposite surface of the protective substrate wafer 130 of the passage forming substrate wafer 110. Subsequently, as shown in (b) of FIG. 5, a protective film 52 having a predetermined pattern and serving as a mask is formed on the surface of the passage forming substrate wafer 110, when an ink passage such as the pressure generating chamber 12 is formed. That is, the protective film 52 including an opening 52a is formed in an area opposite the ink passage such as the pressure generating chamber 12.

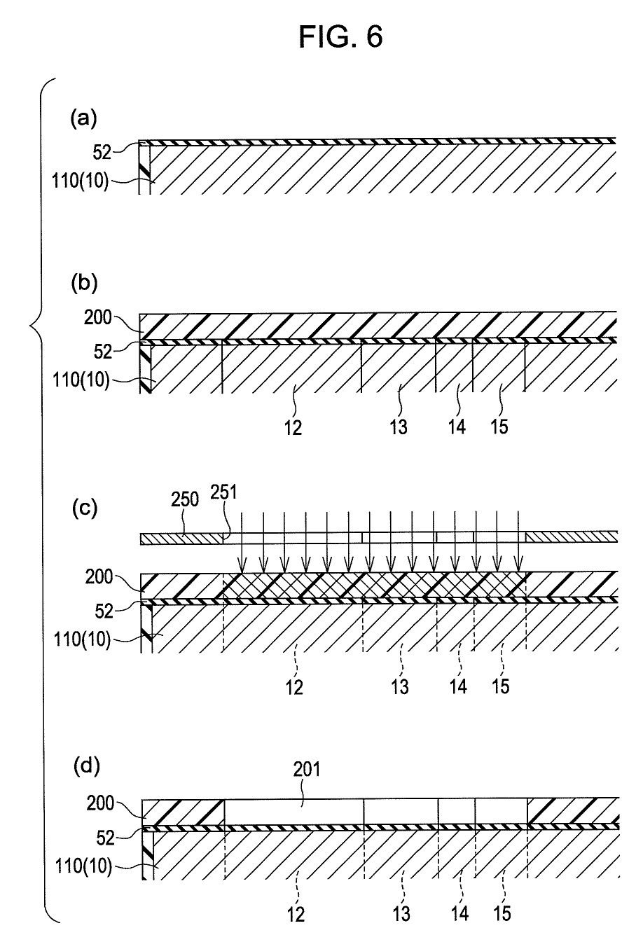

Specifically, as the process of forming the protective film 52 having the predetermined pattern, the protective film 52 formed of silicon nitride (SiN) by a CVD method or the like, for example, is formed on the entire surface of the passage forming substrate wafer 110, as shown in (a) of FIG. 6 (first step). Subsequently, as shown in (b) of FIG. 6, a positive resist is applied on the protective film 52 and subjected to pre-baking at a relatively low temperature of about 100° C., for example, to form the resist film 200 (second step).

Subsequently the resist film 200 is exposed and developed to selectively remove a part of the resist film (third step). In the third step, as shown in (c) of FIG. 6, the resist film 200 is selectively exposed through a mask member 250 having an opening 251 at a predetermined position. That is, the resist film 200 of an area where the ink passage such as the pressure generating chamber 12 is formed is exposed from the opening 251 of the mask member 250. Subsequently, the resist film 200 is developed by a development liquid such as tetramethylammonium hydroxide (TMAH), for example. In this way, as shown in (d) of FIG. 6, the resist film 200 of the area where the ink passage such as the pressure generating chamber 12 is formed is selectively removed to form an opening 201 in the resist film 200.

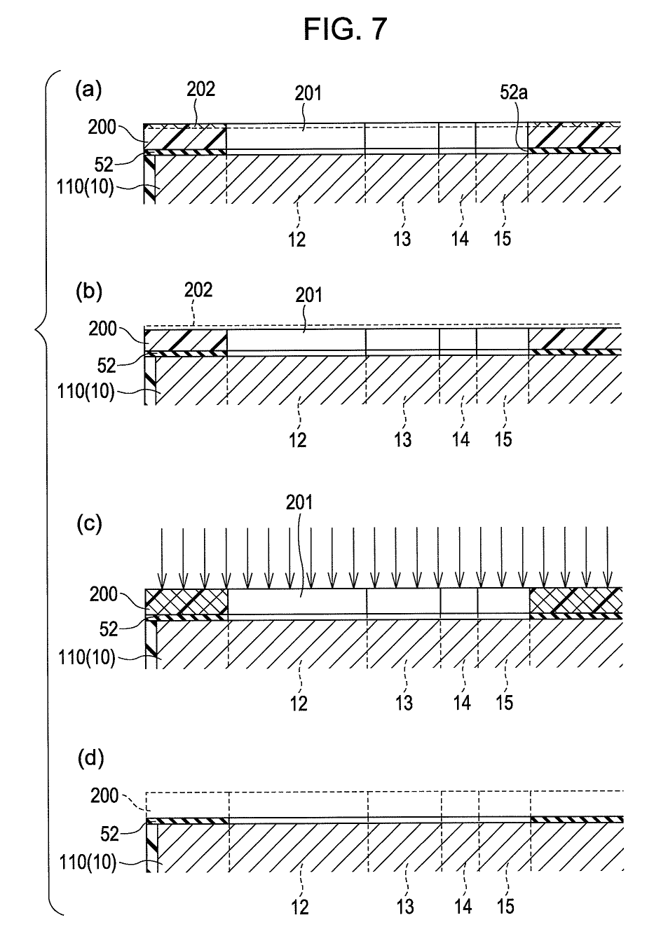

Subsequently, as shown in (a) of FIG. 7, a part of the protective film 52 is selectively removed by performing dry etching on the protective film 52 using the resist film 200 as a mask to form a predetermined pattern (fourth step). Specifically, the opening 52a is formed in the protective film 52 by selectively removing the protective film 52 of the area where the ink passage such as the pressure generating chamber 12 is formed by plasma etching of using carbon tetrafluoride (CF4).

In order to form the opening 52a in the protective film 52 by the dry etching, the dry etching needs to be performed at a temperature equal to or less than the temperature at which the resist film 200 is subjected to the pre-baking. That is, the dry etching needs to be performed on the protective film 52 in a state where the temperature of the passage forming substrate wafer 110 in which the protective film 52 is formed is maintained so as to be the temperature equal to or less than the temperature at which the pre-baking is performed. For example, in this embodiment, the dry etching needs to be performed at 100° C. or less, since the pre-baking is performed at about 100° C. It is preferable that the protective film 52 is subjected to the dry etching in the state where the passage forming substrate wafer 110 is maintained with 80° C. or less.

The photosensitivity of the resist film 200 is not completely lost due to the above process even after the third step. That is, since the temperature higher than the temperature at which the pre-baking is performed is applied to the resist film 200, the photosensitivity of the resist film 200 is not completely lost even after the dry etching.

Here, as shown in FIG. 8, the dry etching of the protective film 52 is performed in a state where a junction layer 150 of the passage forming substrate wafer 110 and the protective substrate wafer 130 is fixed onto the maintenance stage 400 of the dry etching apparatus with the passage forming substrate wafer 110 positioned on the protective substrate wafer 130, that is, in a state where the protective substrate wafer 130 is fixed onto the maintenance stage 400. Since the piezoelectric elements 300 and a wiring pattern (not shown) connected with a driving IC for driving the piezoelectric elements 300 are formed on the outer surface of the protective substrate wafer 130, the entire surface of the protective substrate wafer 130 should not come in contact with the maintenance stage 400. For that reason, a concave portion 401 is provided in the center of the maintenance stage 400 and only the circumference of the protective substrate wafer 130 in the junction layer 150 is fixed to come in contact with the maintenance stage 400.

When the protective film 52 is subjected to the dry etching, the junction layer 150 of the passage forming substrate wafer 110 and the protective substrate wafer 130 is maintained with the relatively low temperature of 80° C., as described above, by maintaining the maintenance stage 400 with about 60° C., for example. In addition, a cooling temperature of the maintenance stage 400 is not particularly limited.

In order to suppress the temperature of the junction layer 150 (the passage forming substrate wafer 110) by controlling the temperature of the maintenance stage 400, a depth d of the concave portion 401 of the maintenance stage 400 is preferably in the range of about 0.1 mm to 0.5 mm and more preferably in the range of about 0.1 mm to 0.2 mm. In this way, a cooling effect obtained by bringing the entire surface of the junction layer 150 into contact with the maintenance stage 400 can be achieved.

If the depth of the concave portion 401 is less than 0.1 mm, the surface of the junction layer 150 (the protective substrate wafer 130) may not be surely protected. In addition, if the depth of the concave portion is larger than 0.5 mm, the junction layer 150 may not be sufficiently cooled. Even if a vacuum state is maintained inside the concave portion 401, the junction layer 150 can be satisfactorily cooled by setting the depth of the concave portion 401 to the above-described range.

After the dry etching on the protective film 52, the resist film 200 is removed in the following order. The photosensitivity of the resist film 200 is not completely lost even when the dry etching on the protective film 52 is performed, as described above. However, the surface of the resist film 200 is turned into a degeneration layer 202 of the resist film 200. For example, since carbon tetrafluoride (CF4) is used in this embodiment, the surface of the resist film 200 is turned into the degeneration layer 202 having a hydrophobic property.

Accordingly, when the resist film 200 is removed, the degeneration layer 202 formed on the surface of the resist film 200 is first removed (fifth step), as shown in (b) of FIG. 7. Specifically, it is preferable that the degeneration layer 202 is removed by supplying ozone water (O3) onto the resist film 200 by use of a spin coat apparatus or the like. In this way, it is possible to satisfactorily remove the degeneration layer 202 without badly affecting the periphery. The concentration of the ozone water is not particularly limited. For example, the ozone water having relatively low concentration in the range of about 10 to 20 ppm may be used. The method of removing the degeneration layer 202 is not limited to the method of using the ozone water, but any method of allowing the photosensitivity of the resist film 200 not to be lost may be used.

The remaining resist film 200 is again exposed, as shown in (c) of FIG. 7, and then the remaining resist film 200 is again developed to completely remove the resist film 200, as shown in (d) of FIG. 7 (sixth step). As described above, the temperature at which the protective film 52 is subjected to the dry etching is set to the temperature equal to or less than the temperature at which the resist film 200 is subjected to the pre-baking. Therefore, even when the dry etching is performed, the photosensitivity of the resist film 200 is not completely lost. Accordingly, by again exposing and developing the resist film 200 formed of the positive resist, it is possible to remove the entire remaining resist film 200 with relative ease.

In the invention, the degeneration layer 202 into which the surface of the resist film 200 is turned is removed before the resist film 200 is again exposed and developed, as described above. Accordingly, by again exposing and developing the resist film 200, it is possible to completely remove the resist film 200. In addition, when the degeneration layer 202 remains on the surface of the resist film 200, the development of the resist film 200 deteriorates due to the degeneration layer 202. For example, in this embodiment, since the degeneration layer 202 has the hydrophobic property, a development liquid is splashed due to the degeneration layer 202 at the time of developing the resist film 200. For that reason, even when the resist film 200 is again exposed and developed in the state where the degeneration layer 202 remains, it is difficult to remove the resist film 200.

After the protective film 52 is formed in this manner, as shown in (c) of FIG. 5, the passage forming substrate wafer 110 is subjected to anisotropic etching (wet etching) by using the protective film 52 as a mask. In this way, the pressure generating chambers 12, the ink supply passages 13, the communication passages 14, and the communication section 15 included in the ink passage are formed in the passage forming substrate wafer 110.

Subsequently, unnecessary portions of the outer circumferences of the passage forming substrate wafer 110 and the protective substrate wafer 130 are cut and removed by dicing, for example. The nozzle plate 20 through which the nozzles 21 are punched is joined onto a surface opposite the protective substrate wafer 130 of the passage forming substrate wafer 110, the compliance substrate 40 is joined to the protective substrate wafer 130, and the passage forming substrate wafer 110 is divided into the passage forming substrates 10 having one chip size, as in FIG. 1, to manufacture the ink jet print head.

The embodiment of the invention has been described. However, of course, the invention is not limited to this embodiment.

For example, in this embodiment, the resist film 200 is not subjected to post-baking. When the thickness of the protective film 52 is relatively thin, the resist film 200 can sufficiently serve as a mask without performing the post-baking at the time of etching the protective film 52. Of course, after the resist film 200 is exposed and developed in the third step, the resist film 200 may be subjected to the post-baking. In this case, a temperature at which the post-baking is performed needs to be a temperature at which the photosensitivity of the resist film 200 is not completely lost. A temperature slightly higher than the temperature at which the pre-baking is performed is preferable, for example, about 120° C. is preferable.

In the above-described embodiment, the ink jet print head including the thin film type piezoelectric elements, which are manufactured by application of a film forming process and a lithographic process, as pressure generating means is used as an example. Of course, the invention is not limited thereto. For example, the invention is applicable to an ink jet print head including another type of pressure generating unit, such as an ink jet print head including a thick film type piezoelectric element formed by attaching a green sheet as a pressure generating unit.

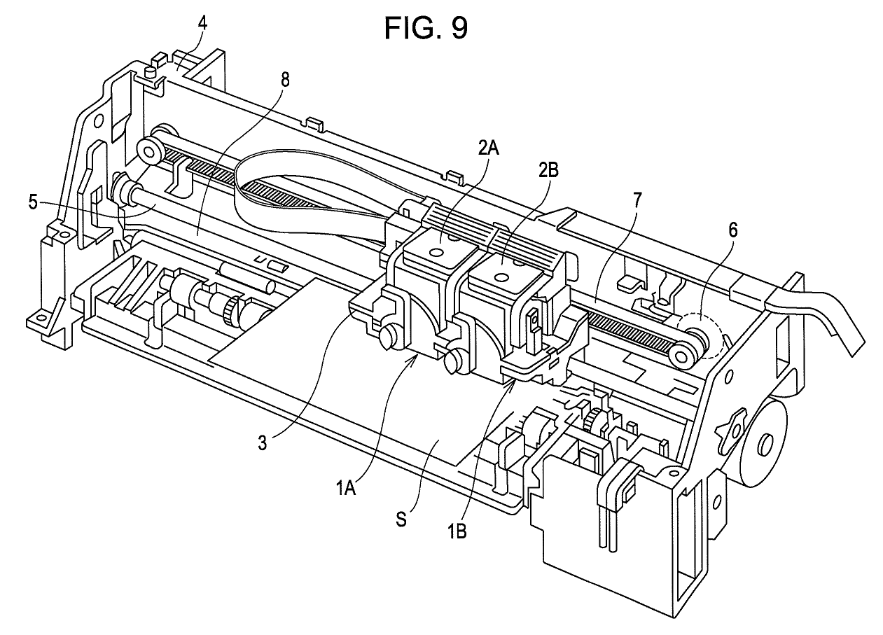

The ink jet print head manufactured in the above-described manner forms a part of a print head unit including an ink passage for communicating with an ink cartridge or the like and is mounted on an ink jet printing apparatus. FIG. 9 is a schematic diagram illustrating an example of the ink jet printing apparatus.

As shown in FIG. 9, print head units 1A and 1B of the ink jet printing apparatus are provided so that cartridges 2A and 2B serving as ink supply means are detachably mounted. A carriage 3 mounted with the print head units 1A and 1B is provided to be freely movable in a shaft direction along a carriage shaft 5 attached to an apparatus main body 4. The print head units 1A and 1B are configured to eject black ink and color ink, respectively, for example.

The carriage 3 mounting the print head units 1A and 1B is moved along the carriage shaft 5 by delivering a driving force of a driving motor 6 to the carriage 3 through a plurality of toothed-gears (not shown) and a timing belt 7. On the other hand, a platen 8 is formed along the carriage shaft 5 in the apparatus main body 4. In addition, a print sheet S as a print medium such as a paper sheet fed by a feeding roller or the like (not shown) is wound by the platen 8 so as to be transported.

In the above-described embodiment, the ink jet printing apparatus in which the ink jet print heads are mounted on the carriage and moved in a main scanning direction has been described. However, the invention is applicable to other ink jet printing apparatuses. For example, the invention is applicable to a so-called line type ink jet printing apparatus which includes plurality of fixed ink jet print heads and performs printing just by moving a print sheet S such as a paper sheet in a sub-scanning direction.

In the above-described embodiment, the ink jet print head has been described as an example of the liquid jet head. However, the invention is the invention is devised so as to be applied to various liquid jet heads. Of course, the invention is applicable to a method of manufacturing the liquid jet head for ejecting a liquid other than ink. Examples of the liquid jet head include various print heads used for an image recording apparatus such as a printer, a color material jet head used to manufacture a color filter such as a liquid crystal display, an electrode material jet head used to form electrodes such as an organic EL display or an FED (Field Emission Display), and a bio organism jet head used to manufacture a bio chip.

1. A method of manufacturing a liquid jet head which includes a passage forming substrate provided with a liquid passage including a pressure generating chamber communicating with a nozzle for ejecting liquid droplets and pressure generating member provided above one surface of the passage forming substrate and generating pressure in the pressure generating chamber, the method comprising:
forming the liquid passage by etching the passage forming substrate by using a protective film, which has a predetermined pattern formed above a surface of the passage forming substrate, as a mask,
forming the protective film above the entire surface of the passage forming substrate, as a process of forming the protective film having the predetermined pattern;
forming a resist film by applying a positive resist on the protective film and subjecting the positive resist to pre-baking;
removing selectively the resist film by selectively exposing and developing the resist film;
removing selectively the protective film by performing dry etching at a temperature equal to or lower than a temperature at which the pre-baking is performed;
removing a degeneration layer formed on a surface of the resist film in removing selectively the resist film; and
removing the resist film by again exposing and developing the resist film.

2. The method according to claim 1, wherein in removing a degeneration layer, the degeneration layer is removed by use of ozone water.

3. The method according to claim 1, wherein in removing selectively the protective film, the protective film is subjected to dry etching at a state where the passage forming substrate is maintained at a temperature of 80° C. or less.

4. The method according to claim 1, wherein the protective film is formed of silicon nitride and in removing selectively the protective film, the protective film is removed by plasma etching by use of carbon tetrafluoride.

5. The method according to claim 1, wherein in removing selectively the resist film, the resist film is selectively removed and then the resist film is additionally subjected to post-baking.

6. A liquid jet head manufactured by the method according to claim 1.

7. A liquid jet apparatus comprising the liquid jet head according to claim 6.
